(19) United States
(12) Patent Application Publication
(10) Pub. No.: US 2025/0172877 A1
(43) Pub. Date: May 29, 2025

(54) REVERSIBLE OVERCOAT COMPOSITIONS

(71) Applicant: Tokyo Electron Limited, Tokyo (JP)

(72) Inventors: Charlotte Cutler, Albany, NY (US); Michael Murphy, Albany, NY (US); David Conklin, Saratoga Springs, NY (US)

(21) Appl. No.: 18/617,951

(22) Filed: Mar. 27, 2024

Related U.S. Application Data
(60) Provisional application No. 63/603,580, filed on Nov. 28, 2023.

(51) Int. Cl. G03F 7/11; C08F 12/24; C08F 20/06; C08F 20/28; C09D 125/18; C09D 133/02; C09D 133/14; G03F 7/16; H01L 21/027

(52) U.S. Cl. CPC G03F 7/11; C08F 12/24; C08F 20/06; C08F 20/28; C09D 125/18; C09D 133/02; C09D 133/14; G03F 7/168; H01L 21/0274; C08F 2810/20

(57) ABSTRACT

Reversible overcoat compositions for overcoating structures during semiconductor microfabrication are described. An example composition includes a first solute with an organic hydroxy functional group, a second solute with an enol ether functional group, and an organic solvent system, with a mole ratio between all of the organic hydroxy functional groups of the first solute and all of the enol ether functional groups of the second solute being between 2.0 and 4.0.

### CROSS-REFERENCE TO RELATED APPLICATIONS

This application claims the benefit of U.S. Provisional Application No. 63/603,580, filed on Nov. 28, 2023, which application is hereby incorporated herein by reference.

### TECHNICAL FIELD

The present invention relates generally to microfabrication of integrated circuits, and in particular to reversible overcoat compositions.

### BACKGROUND

In material processing methodologies, such as photolithography, creating patterned layers typically involves the application of a thin layer of radiation-sensitive material (such as photoresist) to an upper surface of a substrate. This radiation-sensitive material is transformed into a patterned mask that can be used to etch or transfer a pattern into an underlying layer on a substrate. Patterning of the radiation-sensitive material generally involves exposure by a radiation source through a reticle (and associated optics) onto the radiation-sensitive material using, for example, a photolithographic exposure system. This exposure creates a latent pattern within the radiation-sensitive material which can then be developed. “Developing” refers to dissolving and removing a portion of the radiation-sensitive material to yield a relief pattern (topographic pattern). The portion of material removed can be either the irradiated regions or the non-irradiated regions of the radiation-sensitive material, depending on the material's photoresist tone (positive or negative) and/or the type of developing solvent used. The relief pattern can then function as a mask layer defining a pattern.

Application and development of various films used for patterning can include thermal treatment, or “baking.” For example, a newly applied film can receive a post-application bake (PAB) to evaporate solvents and/or to improve material properties such as structural rigidity or etch resistance. A post-exposure bake (PEB) can be executed to set a given pattern and limit or prevent unintended removal of material. Fabrication tools for coating and developing substrates typically include one or more baking modules.

Some photolithography processes include coating with a photoresist, and then exposing the substrate to a pattern of light to create a relief pattern for use as a mask or template for additional processing, such as transferring the pattern into an underlying layer. In related photolithography processes, the substrate may be coated with a thin film of bottom anti-reflective coating (BARC) before coating with a photoresist and then exposing the substrate. These processes may serve as discrete steps in the fabrication of microchips.

### SUMMARY

In accordance with one aspect of the present application, a reversible overcoat composition for overcoating structures during semiconductor microfabrication includes a first solute, which includes an organic hydroxy functional group. The composition includes a second solute including an enol ether functional group, and an organic solvent system, where a ratio between an amount in moles of all of the organic hydroxy functional groups of the first solute and an amount in moles of all of the enol ether functional groups of the second solute is between 2.0 and 4.0.

In accordance with another aspect of the present application, a reversible overcoat composition for overcoating structures during semiconductor microfabrication includes a first solute, which includes a carboxylic acid functional group. The composition includes a second solute including an enol ether functional group, and an organic solvent system, where a ratio between an amount in moles of all of the carboxylic acid functional groups of the first solute and an amount in moles of all of the enol ether functional groups of the second solute is between 2.5 and 4.0.

In accordance with other aspects of the present application, a method of patterning a substrate includes forming a plurality of first mandrels over a substrate; coating an overcoat layer over the plurality of first mandrels, the overcoat layer being coated from a composition including: a first solute including an organic hydroxy functional group, the organic hydroxy functional group not being bound to a carbonyl as part of a carboxylic acid. The composition includes a second solute including an enol ether functional group; and an organic solvent system, where a ratio between an amount in moles of all of the organic hydroxy functional groups of the first solute and an amount in moles of all of the enol ether functional groups of the second solute is between 2.0 and 4.0. The method includes inducing a crosslinking reaction within the overcoat layer that renders the overcoat layer insoluble to a predetermined solvent and forming a crosslinked overcoat layer. The method includes exposing the substrate to a radiation to generate a plurality of acid particles within the plurality of first mandrels, and diffusing a portion of the plurality of acid particles from the plurality of first mandrels into portions of the crosslinked overcoat layer. The method includes inducing a decrosslinking reaction within the portions of the crosslinked overcoat layer and form de-crosslinked regions, where unmodified regions of the crosslinked overcoat layer form a plurality of second mandrels; and selectively removing the de-crosslinked regions, where the plurality of first mandrels and the plurality of second mandrels form a mandrel pattern over the substrate.

In accordance with other aspects of the present application, a method of patterning a substrate includes forming a plurality of first mandrels over a substrate, and coating an overcoat layer over the plurality of first mandrels, the overcoat layer being coated from a composition including: a first solute including a carboxylic acid functional group. The composition includes a second solute including an enol ether functional group; and an organic solvent system, where a ratio between an amount in moles of all of the carboxylic acid functional groups of the first solute and an amount in moles of all of the enol ether functional groups of the second solute is between 2.5 and 4.0. The method includes inducing a crosslinking reaction within the overcoat layer that renders the overcoat layer insoluble to a predetermined solvent and forming a crosslinked overcoat layer. The method includes exposing the substrate to a radiation to generate a plurality of acid particles within the plurality of first mandrels, and diffusing a portion of the plurality of acid particles from the plurality of first mandrels into portions of the crosslinked overcoat layer. The method includes inducing a decrosslinking reaction within the portions of the crosslinked overcoat layer and form de-crosslinked regions, where unmodified regions of the crosslinked overcoat layer form a plurality of second mandrels; and selectively removing the de-crosslinked regions, where the plurality of first mandrels and the plurality of second mandrels form a mandrel pattern over the substrate.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1I illustrate cross-sectional views of different stages of a method for forming a mandrel pattern in accordance with various embodiments;

FIG. 2 illustrates a flow diagram of a method for forming a mandrel pattern in accordance with various embodiments;

FIG. 3 illustrates components of forming overcoat structures described, e.g., in FIGS. 1A-2, with a first solute and a second solute during a lithographic patterning process in accordance with various embodiments;

FIG. 4 illustrates components of a material for overcoat structures with a first solute and a second solute during a lithographic patterning process in accordance with various embodiments;

FIG. 5 illustrates several possible choices of the first solute including poly(4-hydroxystyrene) and poly(hydroxyethylmethacrylate) in accordance with various embodiments;

FIGS. 6A and 6B illustrate two possible choices of the second solute including a multifunctional crosslinker in accordance with various embodiments, wherein FIG. 6A includes two vinyl ether moieties and FIG. 6A includes three vinyl ether moieties;

FIG. 7 illustrates a possible choice of the organic solvent system in accordance with various embodiments;

FIG. 8 illustrates components of material for overcoat structures with a first solute and a second solute during a lithographic patterning process, the first solute including a carboxylic acid functional group, a second solute including an enol ether functional group in accordance with various embodiments;

FIG. 9 illustrates a material for overcoat structures with a first solute and a second solute during a lithographic patterning process in accordance with various embodiments;

FIG. 10 illustrates several possible choices of the first solute of FIG. 9 including poly(methacrylic acid) in accordance with an embodiment; and

FIG. 11 presents results of developer tests performed by the inventors on various compositions of matter for overcoating structures during semiconductor fabrication, including embodiments of the compositions illustrated in FIGS. 3 and 4.

### DETAILED DESCRIPTION OF ILLUSTRATIVE EMBODIMENTS

Ever continuous scaling requires improved patterning resolution. One approach is spacer technology, which defines a sub-resolution line feature via atomic layer deposition (ALD). One challenge for spacer technology arises when there is a need to create features with opposite tone from the deposited material. In such cases, spacer techniques can involve a complex and costly succession of steps, including over-coating with another material (an “overcoat”) using the spacer features as mandrels; chemical-mechanical planarization (CMP) to reveal the spacer features; and reactive ion etching (RIE) to remove the spacer material, leaving a narrow trench.

Anti-spacer technology is an alternate, self-aligned approach that uses the diffusion length of a reactive species across the boundary between the overcoat and an adjacent layer to define a critical dimension (CD), creating a narrow trench around the features of that adjacent layer after development of the overcoat. When generation of the reactive species is controlled spatially via exposure through a mask, finer features can be formed, such as a narrow slot contact. The CD itself can be tuned based on the physical and chemical properties of the reactive species (e.g., its molecular weight and affinity for interactions with the host material) and by modifying the bake temperature and bake time in a post exposure bake (PEB). As a result, anti-spacer techniques enable patterning narrow slot-contact features at dimensions beyond the reach of advanced lithographic capabilities.

Anti-spacer formation is a means to achieve self-aligned double patterning (SADP) through spin-on processes, thereby improving throughput and overall cost. Additionally, limitations of conventional SADP processes, such as resolving a single CD across an entire substrate, can be overcome with anti-spacer processes. Because features are formed by the physical generation and subsequent diffusion of a solubility-changing species across an interface, the formation and mobility of the diffusing species can be modulated across the substrate to enable multiple feature widths in a single process. The density of the final pattern, however, is limited within anti-spacer flows exhibiting change in CD of a single mandrel, as is particularly apparent when the final target pitch is approaching one-half the resolution limit of the lithographic exposure. To achieve a 1:1 line-space (L/S) mandrel pattern (e.g., equal pitch between mandrels), the initial lithographic exposure is biased to account for the addition of a mandrel or anti-spacer and achieve the target pitch.

When the target pitch approaches one-half the resolution limit of the lithographic exposure, the correct bias is no longer resolvable, and additional post-exposure processes must be employed. Resolution limitation of the employed lithographic technology prevents desired biasing of the incoming L/S pattern to enable symmetrical L/S patterning, which results in asymmetrical L/S patterning post-multi-patterning processing. In particular, some features remain limited by the resolution of the photolithography process.

Embodiments described in this disclosure provide compositions and formulations for a reversible overcoat for use in an anti-spacer patterning scheme to achieve sub-lithographic mandrel patterns. The scheme relies on diffusion of a solubility-changing species outward from the photoresist mandrels into the reversible overcoat to cause a reaction resulting in the formation of narrow trenches. The resulting process flow overcomes the pitch limitation of an acid-in unidirectional diffusion process flow using a post-lithographic trim of the photoresist mandrels to resolve the required bias of the line-space pattern to achieve a final symmetrical mandrel pattern.

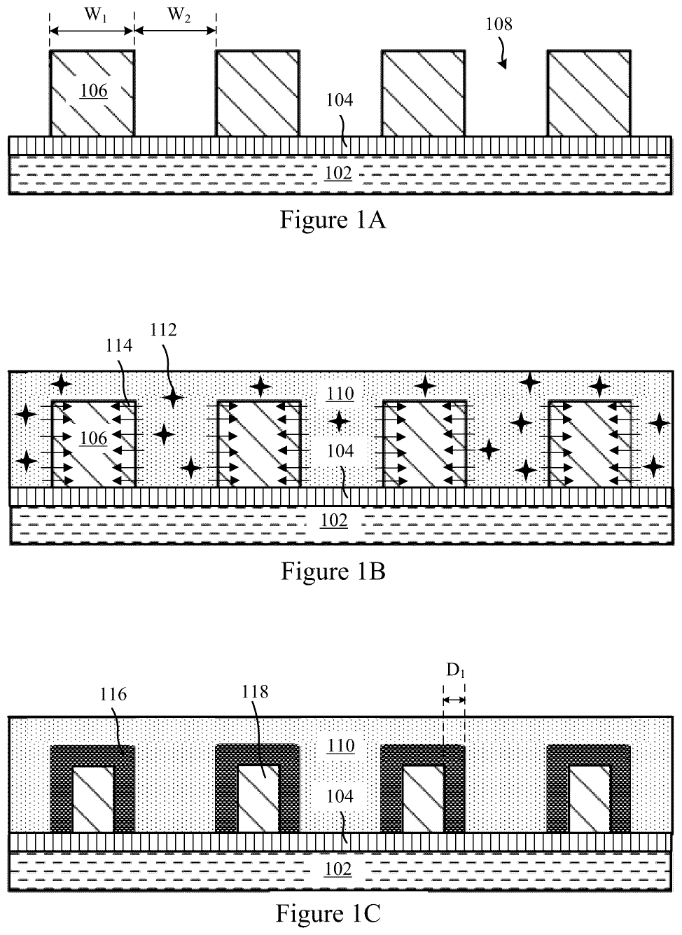

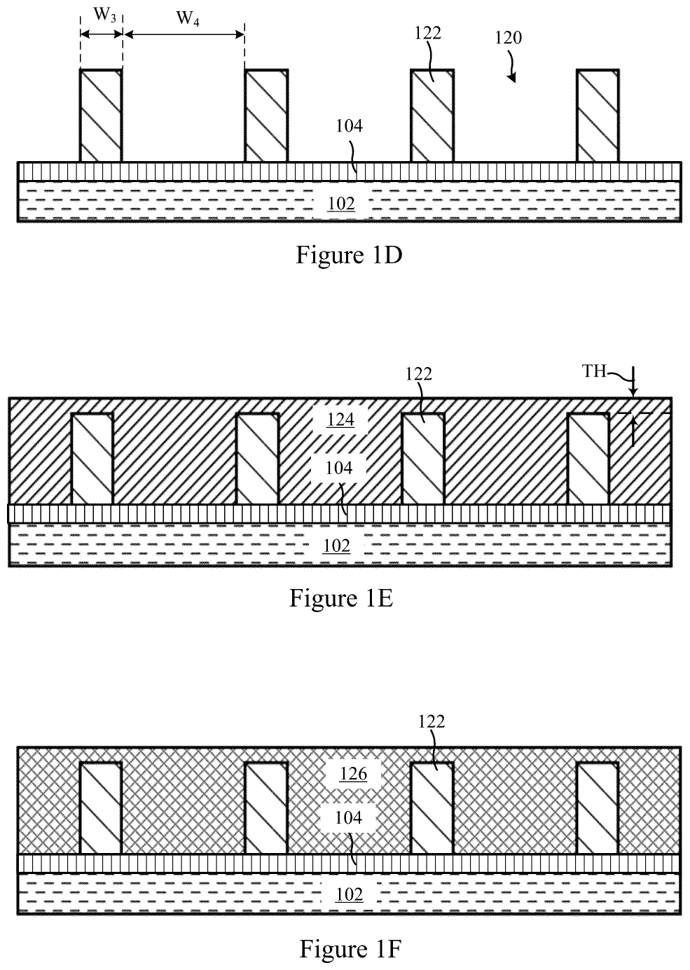

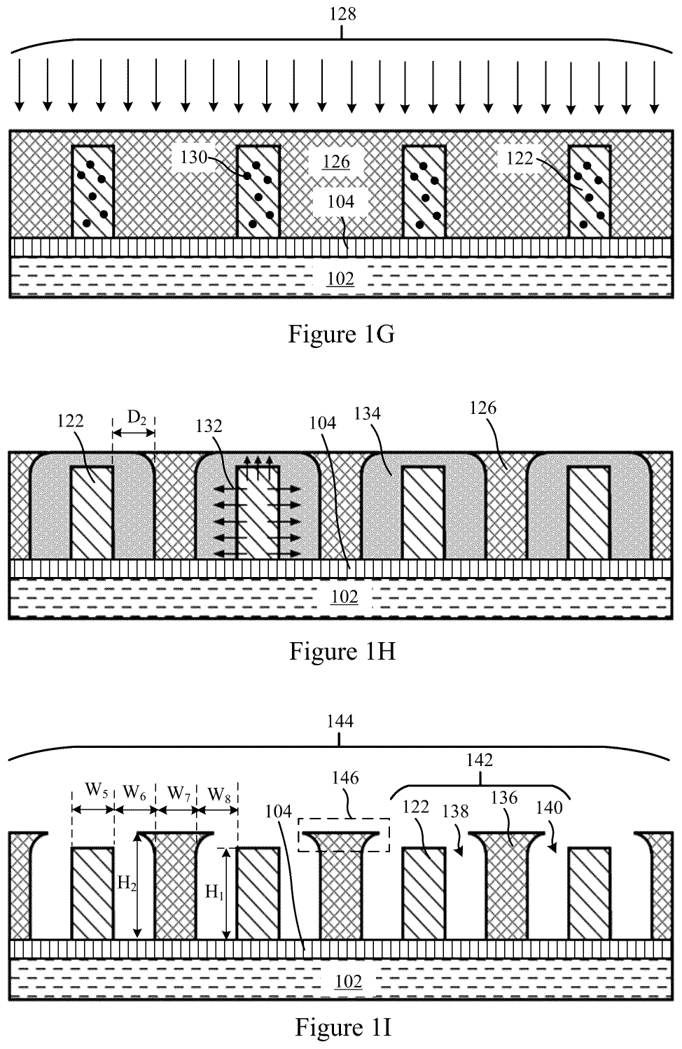

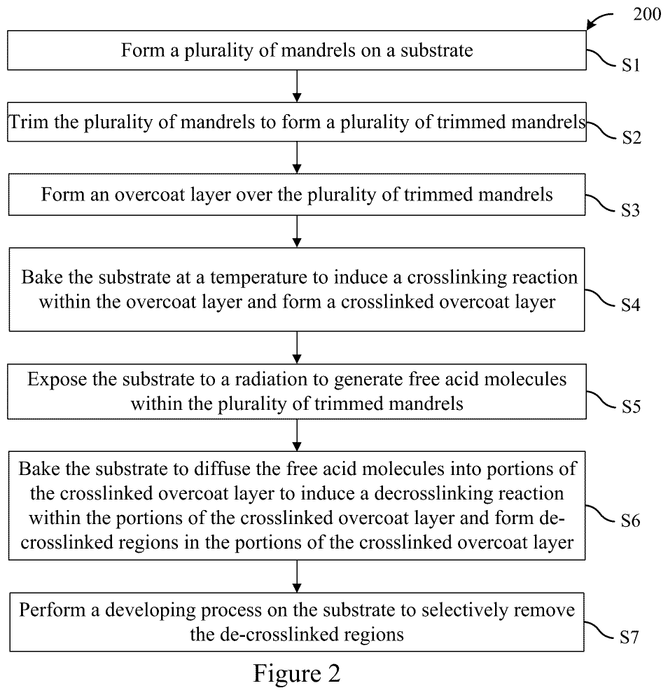

FIGS. 1A-1I illustrate cross-sectional views of different stages of a method for forming a mandrel pattern for a pitch-splitting process flow illustrated in FIG. 2.

Referring to FIG. 1A, a plurality of mandrels 106 are formed over a substrate 102 (Box S1 of FIG. 2). The substrate 102 may be a part of, or include, a semiconductor device or a semiconductor structure, and may be formed in any suitable manner, including using any suitable combination of wet and/or dry deposition, photolithography and etch techniques. For example, the semiconductor structure may comprise the substrate 102 in which various device regions are formed. In certain embodiments, the substrate 102 may include isolation regions such as shallow trench isolation (STI) regions, diffusion regions, as well as other regions formed therein.

The substrate 102 may comprise layers of semiconductors suitable for various microelectronics. In one or more embodiments, the substrate 102 may be a silicon wafer, or a silicon-on-insulator (SOI) wafer. In certain embodiments, the substrate 102 may comprise a silicon germanium wafer, silicon carbide wafer, gallium arsenide wafer, gallium nitride wafer, or other compound semiconductors. In other embodiments, the substrate 102 may comprise heterogeneous layers such as silicon germanium on silicon, gallium nitride on silicon, silicon carbon on silicon, or layers of silicon on a silicon or SOI substrate. In various embodiments, the substrate 102 is patterned or embedded in other components of the semiconductor device or the semiconductor structure.

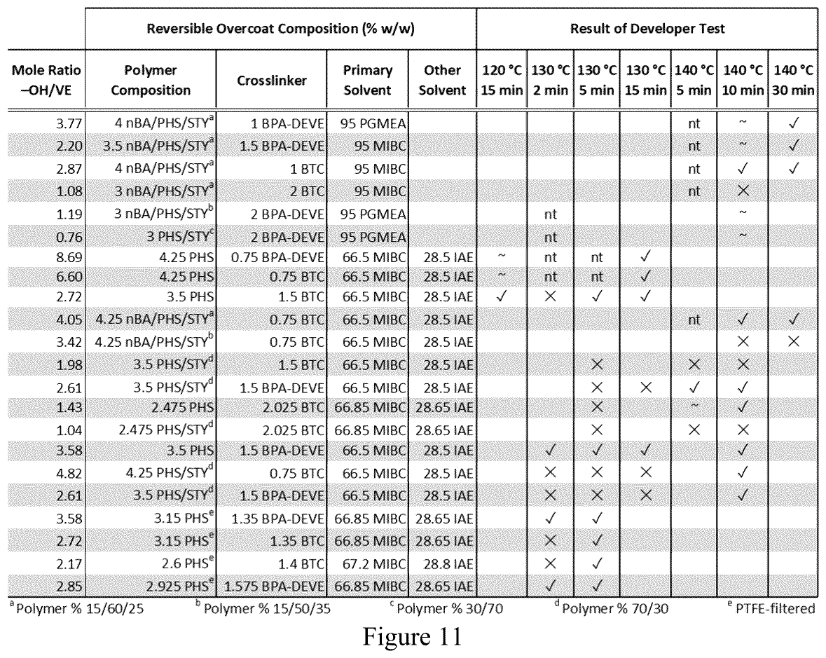

Referring further to FIG. 1A, in some embodiments, an intermediate layer 104 is formed over the substrate 102 such that the mandrels 106 are formed over the intermediate layer 104. The intermediate layer 104 may be a target for pattern transfer in subsequent processing after formation of the mandrel pattern 144 (see FIG. 11) is completed. The intermediate layer 104 may comprise silicon, silicon oxynitride, organic material, non-organic material, amorphous carbon, or the like. The intermediate layer 104 may be selected to have anti-reflective properties such as by using a silicon bottom anti-reflective coating (Si-BARC), for example. The intermediate layer 104 may be a mask layer comprising a hard mask. Further, the intermediate layer 104 may be a stacked hard mask comprising, for example, two or more layers of two or more different materials. In embodiments when the hard mask comprises two layers, a first layer of the hard mask may comprise a metal-based layer such as titanium nitride, titanium, tantalum nitride, tantalum, tungsten-based compounds, ruthenium-based compounds, or aluminum-based compounds, and a second layer of the hard mask may comprise a dielectric layer such as silicon dioxide, silicon nitride, silicon oxynitride, silicon carbide, amorphous silicon, or polycrystalline silicon. The intermediate layer 104 may be deposited using suitable deposition processes. Suitable deposition processes may include a spin-on coating process, a chemical vapor deposition (CVD) process, an atomic layer deposition (ALD) process, plasma deposition processes (e.g., a plasma-enhanced CVD (PECVD) process, or a plasma-enhanced ALD (PEALD) process), and/or other layer deposition processes or combinations of processes.

In some embodiments, the mandrels 106 may be formed by forming a photoresist layer (not shown) over the intermediate layer 104 and patterning the photoresist layer using suitable photolithographic techniques. The photoresist layer may comprise a positive-tone photoresist or a negative-tone photoresist. In the illustrated embodiment, the photoresist layer comprises a positive-tone chemically amplified photoresist (CAR). The photoresist layer may be deposited on the substrate 102 in any suitable manner. For example, the photoresist layer may be deposited by spin-coating, spray-coating, dip-coating, or roll-coating. As a particular example, the photoresist layer may be deposited on the substrate 102 using a spin-on deposition technique, which may be also referred to as spin-coating. In various embodiments, the photoresist layer may comprise an agent-generating ingredient that, in response to a suitable agent-activation trigger (e.g., heat or radiation), generates a solubility-changing agent (e.g., an acid). Example agent-generating ingredients may include a thermal-acid generator (TAG) that is configured to generate an acid in response to heat or a photo-acid generator (PAG) that is configured to generate an acid in response to actinic radiation.

With spin-on deposition, a particular material (e.g., a material of the photoresist layer) is deposited on the substrate 102 (e.g., on the intermediate layer 104 formed on the substrate 102). The substrate 102 is then rotated (if not already rotating, possibly at a relatively low velocity) at a relatively high velocity so that centrifugal force causes the deposited material to move toward edges of the substrate 102, thereby coating the substrate 102. Excess material is typically spun off the substrate 102. In certain embodiments, the spin-on deposition technique includes dispensing liquid chemicals onto the substrate 102 (e.g., on a top surface of the intermediate layer 104) using a coating module with a liquid delivery system that may dispense one or more types of liquid chemicals. The dispense volume can be in a range from 0.2 mL to 10 mL, for example, in a range from 0.5 mL to 2 mL. The substrate 102 may be secured to a rotating chuck that supports the substrate 102. The rotating speed during the liquid dispense can be in a range from 50 rpm to 3000 rpm, for example, in a range from 1000 rpm to 2000 rpm. The system may also include an anneal module that may bake or apply light radiation to the substrate 102 after the chemicals have been dispensed. It should be understood that this example spin-on deposition technique and associated values are provided as examples only. In other embodiments, the photoresist layer may be deposited using a CVD process, a plasma-enhanced CVD process, an ALD process, or other suitable processes.

After forming the photoresist layer, a reticle (not shown) is disposed over the photoresist layer. The reticle may be used to modulate a dose (or an intensity) of a radiation (e.g., actinic radiation) that is used to expose the photoresist layer. In such embodiments, the reticle may comprise regions of different transparency to the radiation (e.g., opaque and transparent regions). The photoresist layer is then subject to an exposure step through the reticle. The radiation exposes exposed regions of the photoresist layer while unexposed (or unmodified) regions of the photoresist layer are protected by the reticle. The exposure step may be performed using a photolithographic technique such as dry lithography (e.g., using 193-nanometer dry lithography), immersion lithography (e.g., using 193-nanometer immersion lithography), i-line lithography (e.g., using 365-nanometer wavelength UV radiation for exposure), H-line lithography (e.g., using 405-nanometer wavelength UV radiation for exposure), extreme UV (EUV) lithography, deep UV (DUV) lithography, or any suitable photolithography technology.

In some embodiments, the radiation generates an acid in the exposed regions of the photoresist layer. The acid may be generated from the PAG that is present in the photoresist layer under the influence of the radiation. The acid may react with the material of the photoresist layer and alter the solubility of the exposed regions of the photoresist layer. Subsequently, the exposed regions of the photoresist layer are removed by performing a developing process using a suitable developer. The developing process forms a plurality of openings 108 in the photoresist layer that expose portions of the intermediate layer 104. The unexposed regions of the photoresist layer form the plurality of mandrels 106.

The mandrels 106 may have a first width W₁ and the openings 108 may have a second width W₂. In some embodiments, the first width W₁ and/or the second width W₂ may have smallest values that are achievable by photolithographic techniques. In the illustrated embodiment, a ratio W₁:W₂ equals 1:1.

Referring to FIG. 1B, an overcoat layer 110 is deposited over the substrate 102 in any suitable manner. For example, the overcoat layer 110 may be deposited by spin-coating, spray-coating, dip-coating, or roll-coating. As a particular example, the overcoat layer 110 may be deposited on the substrate 102 using a spin-on deposition technique, which may be also referred to as spin-coating. The spin-on deposition technique has been described above with reference to FIG. 1A and the description is not repeated herein. The overcoat layer 110 may be also referred to as a trim layer. The overcoat layer 110 may fill the openings 108 (see FIG. 1A) and cover top surfaces of the mandrels 106.

A material for the overcoat layer 110 may be chosen such that the overcoat layer 110 could be removed in a subsequent developing process, as described below in greater detail. In some embodiments, the overcoat layer 110 may be a multicomponent material that, as deposited, includes a first component and a second component. The first component could be, for example, a polymer. The second component could be, for example, a solubility-changing agent 112, such as an acid (e.g., a free acid). In the illustrated embodiment, the solubility-changing agent 112 comprises a plurality of acid particles that are depicted as filled 4-pointed stars in FIG. 1B. The second component could be, as another example, an agent-generating ingredient that, in response to a suitable agent-activation trigger (e.g., heat or radiation), generates a solubility-changing agent (e.g., an acid). Example agent-generating ingredients may include a TAG that is configured to generate an acid in response to heat or a PAG that is configured to generate an acid in response to actinic radiation.

For example, in the case of the overcoat layer 110 including a free acid, a solubility-changing agent 112 may be the free acid and subsequent baking of the substrate 102 may cause the free acid to diffuse (as indicated by arrows 114) into perimeter portions of the mandrels 106 and cause the perimeter portions of the mandrels 106 to become soluble in a developer.

As another example, in the case of the overcoat layer 110 including a TAG as an agent-generating ingredient, subsequent baking of the substrate 102 may cause the TAG to generate a solubility-changing agent 112 (e.g., acid), which may be referred to as activating the acid, cause the generated solubility-changing agent 112 to diffuse (as indicated by arrows 114) into perimeter portions of the mandrels 106, and cause the perimeter portions of the mandrels 106 to become soluble in a developer.

As another example, in the case of the overcoat layer 110 including a PAG as an agent-generating ingredient, an exposure step that includes exposing the overcoat layer 110 to a radiation (e.g., actinic radiation) may be performed prior to baking the substrate 102. The exposure step may cause the PAG to generate a solubility-changing agent 112 (e.g., acid), which may be referred to as activating the acid. Baking of the substrate 102 may cause the generated solubility-changing agent 112 to diffuse (as indicated by arrows 114) into perimeter portions of the mandrels 106 and cause the perimeter portions of the mandrels 106 to become soluble in a developer.

Referring to FIG. 1C, a baking process is performed on the substrate 102. In certain embodiments, the baking process may be a thermal process that is performed by heating the substrate 102 in a process chamber to a temperature between 50° C. and 250° C., for example, between 60° C. and 140° C. in certain embodiments, in vacuum or under a gas flow. In a particular example, the substrate 102 is baked for a duration in a range from 1 to 3 minutes. The bake conditions may be selected to promote the diffusion of the solubility-changing agent 112 (and possibly generation of the solubility-changing agent 112 from an agent-generating ingredient of the overcoat layer 110, if applicable) and associated change in solubility of the perimeter regions of the mandrels 106 (see FIG. 1B) to a target first depth D₁. The first depth D₁ may be tuned by parameters of the baking process (such as, for example, a bake temperature and a bake duration) and material parameters (such as, for example, a polymer composition of the mandrels 106, and an acid composition and an acid concentration in the overcoat layer 110).

Referring to FIG. 1C, the solubility-changing agent 112 chemically reacts with a material of the mandrels 106 to form modified regions 116 of the mandrels 106. The chemical reaction changes the solubility of the modified regions 116 of the mandrels 106 so that the modified regions 116 of the mandrels 106 can be removed in a subsequent developing process. Each modified region 116 extends along sidewalls and a top surface of an unmodified region 118 of a respective mandrel 106 (see FIG. 1C).

Referring to FIG. 1D, a developing process is performed on the substrate 102 using a suitable developer. In various embodiments, the developer may comprise a metal ion-free (MIF) developer, for example, an aqueous solution of tetramethylammonium hydroxide (TMAH). In other embodiments, the developer solution may comprise a metal ion-containing developer, for example, an aqueous solution of sodium hydroxide (NaOH) or potassium hydroxide (KOH). In some embodiments, the developing process may comprise dipping or soaking the substrate 102 in the developer.

In some embodiments, the developer removes the overcoat layer 110 (see FIG. 1C) and the modified regions 116 (see FIG. 1C), and forms openings 120 that expose the intermediate layer 104. Remaining unmodified regions 118 (see FIG. 1C) of the mandrels 106 form a plurality of mandrels 122 over the intermediate layer 104. The steps described using FIGS. 1B-1D may be collectively described as forming trimmed mandrels (Box S2 of FIG. 2).

The mandrels 122 may have a third width W₃ and the openings 120 may have a fourth width W₄. The third width W₃ of the mandrels 122 is less than the first width W₁ of the mandrels 106 (see FIG. 1A). In some embodiments, when the first width W₁ has the smallest value achievable by the photolithography process, the mandrels 122 have a sub-lithographic width. The fourth width W₄ of the openings 120 is greater than the second width W₂ of the openings 108 (see FIG. 1A). In the illustrated embodiment, a ratio W₃:W₄ equals 1:3. Such a pattern of the mandrels 122 may be also referred to as a 1:3 line-space (L/S) pattern. In other embodiments, a ratio W₃:W₄ may be in a range from 1:2 to 1:5.

Referring to FIG. 1E, an overcoat layer 124 is deposited over the substrate 102 in any suitable manner (Box S3 of FIG. 2). For example, the overcoat layer 124 may be deposited by spin-coating, spray-coating, dip-coating, or roll-coating. As a particular example, the overcoat layer 124 may be deposited on the substrate 102 using a spin-on deposition technique, which may be also referred to as spin-coating. The spin-on deposition technique has been described above with reference to FIG. 1A and the description is not repeated herein. The overcoat layer 124 may be also referred to as a reversible overcoat (ROC) layer. The overcoat layer 124 may fill the openings 120 (see FIG. 1D) and cover top surfaces of the mandrels 122. The overcoat layer 124 may have a thickness TH over the top surfaces of the mandrels 122.

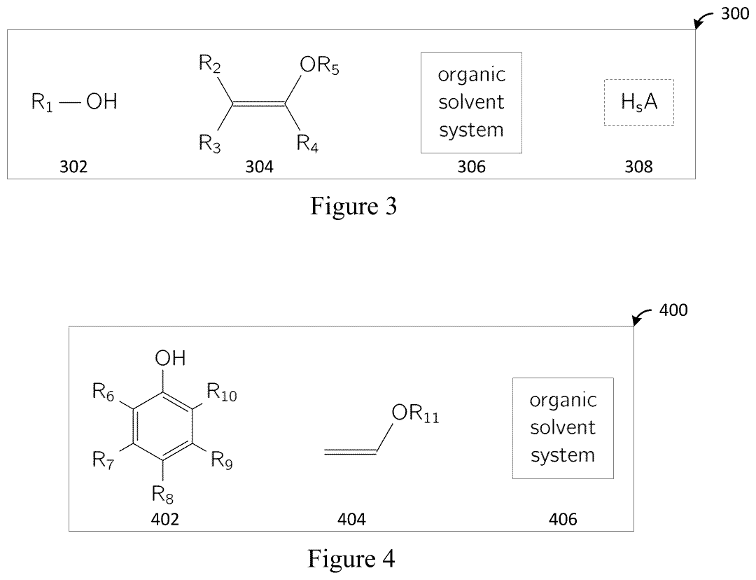

A material of the overcoat layer 124 may be selected not to intermix with a material of the mandrels 122. The material of the overcoat layer 124 may comprise various solutes in an application-specific organic solvent system and will be described in more detail below starting with FIG. 3.

In various embodiments, the material of the overcoat layer 124 may comprise a first solute and a second solute in a solvent. The first solute may comprise a moiety capable of reacting with a moiety of a second solute to create an acetal bond (or “crosslink”). As described in greater detail below, such moieties in one solute may comprise an organic hydroxy functional group or a carboxylic acid functional group; in the other solute, such moieties may be an enol ether functional group (e.g., a vinyl ether) or an N-methoxymethylamide functional group. In some embodiments, the solutes may possess multiple functional groups capable of crosslinking. In certain embodiments, additional solutes may be included in the composition, such as a third solute comprising a weak acid that catalyzes the crosslinking reaction (“the catalyst”).

In some embodiments, one solute may be a polymer and the other may be a small molecule with mass below 1000 daltons. In such embodiments, the small molecule may be referred to as a “crosslinking agent” or “crosslinker.” In other embodiments, both solutes may be polymers, and the solute present in the composition in lower abundance may be referred to as the crosslinking agent, while that present in greater abundance may be referred to simply as “the polymer.” In embodiments in which the solutes are present in equal abundance, the solute comprising enol ether or N-methoxmethylamide functional groups may be referred to as the crosslinking agent, while the other solute may be referred to simply as “the polymer.”

The crosslinking agent can have a function of reacting with the polymer to promote hardening of the composition of the overcoat layer 124. The crosslinking agent may further enable formation of an insoluble network via the formation of acetal bonds between the crosslinking agent and the polymer.

The catalyst present in certain embodiments may function to decrease an activation energy to initiate crosslinking (e.g., lower bake temperature and/or reduce bake time). The catalyst may include a sulfonic acid such as p-toluenesulfonic acid (pTSA), dodecylbenzenesulfonic acid, a mixture thereof, or the like. In some embodiments, the catalyst may be omitted.

Referring to FIG. 1F, after depositing the overcoat layer 124, a baking process is performed on the substrate 102 to induce crosslinking within the overcoat layer 124, thereby making the crosslinked overcoat layer 126 insoluble in a subsequently used developer (Box S4 in FIG. 2). In certain embodiments, the baking process may be a thermal process that is performed by heating the substrate 102 in a process chamber to a temperature between 50° C. and 300° C., in vacuum or under a gas flow. In an implementation, the baking may be performed at a temperature less than 150° C. for less than 6 minutes.

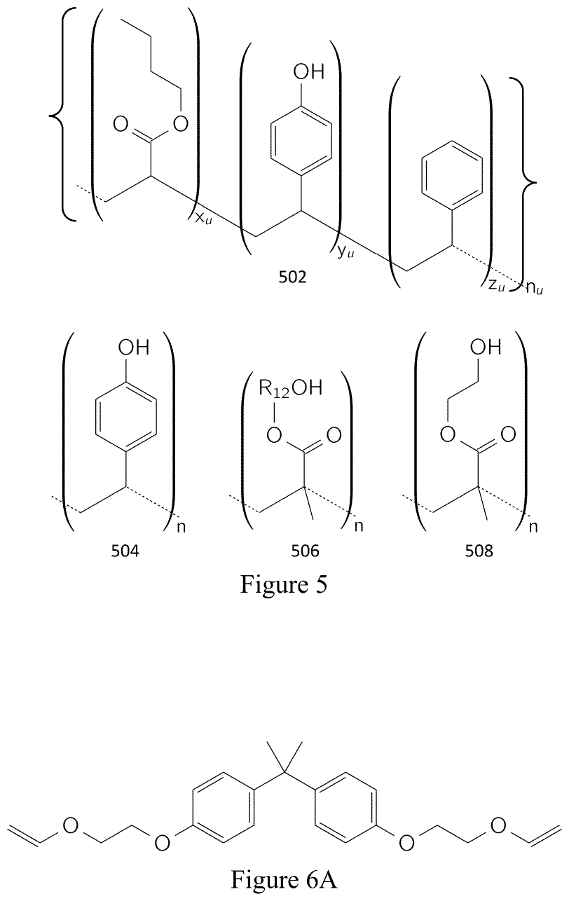

Referring to FIG. 1G, agent-generating ingredients within the mandrels 122 are decomposed to generate a solubility-changing agent 130 (e.g., free acid) (Box S5 in FIG. 5). In the illustrated embodiment, the solubility-changing agent 130 comprises a plurality of acid particles that are depicted as filled circles in FIG. 1G. In some embodiments when the agent-generating ingredients comprise a PAG, the solubility-changing agent 130 (e.g., free acid) is generated in response to exposing the mandrels 122 to a radiation 128 (e.g., actinic radiation). In some embodiments, the substrate 102 is flood exposed to the radiation 128. In such embodiments, each mandrel 122 comprises a substantively similar amount of the solubility-changing agent 130 (e.g., free acid).

Referring to FIG. 1H, a baking process is performed on the substrate 102 (Box S6 in FIG. 2). The baking process diffuses (as indicated by arrows 132) the solubility-changing agent 130 out of the mandrels 122, across interfaces between the mandrels 122 and the crosslinked overcoat layer 126 and into the crosslinked overcoat layer 126 causing de-crosslinking reactions within the crosslinked overcoat layer 126 to a target second depth D₂ to form de-crosslinked regions 134. The de-crosslinked regions 134 may be also referred to as anti-spacers. In certain embodiments, the baking process may be a thermal process that is performed by heating the substrate 102 in a process chamber to a temperature between 50° C. and 300° C., in vacuum or under a gas flow. In an implementation, the baking may be performed at a temperature less than 150° C. for less than 6 minutes.

The second depth D₂ may be tuned by parameters of the baking process (such as, for example, a bake temperature and a bake duration) and material parameters (such as, for example, a polymer composition of the crosslinked overcoat layer 126, and an acid composition and an acid concentration in the mandrels 122). In some embodiments, the second depth D₂ and the thickness TH of the overcoat layer 124 (see FIG. 1E) may be tuned such that the second depth D₂ is greater than the thickness TH. In such embodiments, the solubility-changing agent 130 (see FIG. 1G) diffuses (as indicated by arrows 132) from the top surfaces of the mandrels 122 to a top surface of the crosslinked overcoat layer 126, such that top surfaces of the de-crosslinked regions 134 are exposed and are level with a top surface of the crosslinked overcoat layer 126.

Referring to FIG. 1I, a developing process is performed on the substrate 102 using a suitable developer (Box S7 in FIG. 2). The suitable developer may comprise an organic solvent that is selective to the de-crosslinked regions 134 (see FIG. 1H). In some embodiments, a solubility of the de-crosslinked regions 134 in the suitable developer is greater than a solubility of the crosslinked overcoat layer 126 in the suitable developer and a solubility of the first mandrels 122 in the suitable developer. The developing process selectively removes the de-crosslinked regions 134 to form first and second openings 138 and 140 that expose the intermediate layer 104. Remaining regions of the crosslinked overcoat layer 126 form a plurality of mandrels 136. The first and second mandrels 122 and 136 form a mandrel pattern 144 on the substrate 102. In some embodiments, the first mandrels 122 have a first height H₁ and the second mandrels 136 have a second height H₂, with the second height H₂ being greater than the first height H₁. In some embodiments, a width of the second mandrels 136 increases as the second mandrels 136 extend away from the substrate 102. In such embodiments, the second mandrels 136 comprise overhang regions 146 that overhang the first and the second openings 138 and 140.

In some embodiments, the mandrel pattern 144 comprises a plurality of mandrel patterns 142. Each mandrel pattern 142 comprises first and second mandrels 122 and 136, and first and second openings 138 and 140, with the first opening 138 being interposed between the first mandrel 122 and the second mandrel 136, and the second mandrel 136 being interposed between the first opening 138 and the second opening 140. The first mandrel 122 may have a fifth width W₅, the second mandrel 136 may have a seventh width W₇, the first opening 138 may have a sixth width W₆, and the second opening 140 may have a width W₈. In the illustrated embodiment, a ratio W₅:W₆:W₇:W₈ equals 1:1:1:1. In such embodiments, the mandrel pattern 144 may be also referred to as a 1:1:1:1 L/S pattern. In other embodiments, the ratio W₅:W₆:W₇:W₈ may be equal to 1:X:(3-2X):X, where X is the second depth D₂ as measured in units of the fifth width W₅, with X being in a range from 0 to 3/2. In some embodiments, the pattern of the mandrel pattern 144 may be tuned by tuning X (i.e., by tuning the second depth D₂). In an example when X=1 (i.e., when D₂=W₅), the mandrel pattern 144 is the 1:1:1:1 L/S pattern.

In some embodiments, a pattern of the mandrel pattern 144 is transferred into the intermediate layer 104. For example, the intermediate layer 104 may be etched by an anisotropic etching process, such as reactive ion etch (RIE), while using the mandrel pattern 144 as an etch mask. In various embodiments, the transferred pattern may be used to form a contact hole, a via, a metal line, gate line, isolation region, and other features useful in semiconductor fabrication.

Embodiments of this application disclose compositions for an overcoat film. These compositions enable the film to be crosslinked and subsequently de-crosslinked—such that they are “reversible overcoats,” or ROCs—through processing steps compatible with advanced pitch-splitting process flows like that described above. In particular, the compositions disclosed herein provide ROCs appropriate for application to a substrate 102 to form the overcoat layer 124 (see FIG. 1E) and subsequently to undergo crosslinking to form the crosslinked overcoat layer 126 (see FIGS. 1F-1H). ROCs formulated according to the compositions disclosed herein may then be de-crosslinked by generation and diffusion of free acid, forming the de-crosslinked regions 134 (or anti-spacers) of FIG. 1H. These de-crosslinked regions 134 may then be developed using a predetermined solvent, forming first openings 138 that reveal any intermediate layer 104.

The crosslinking reaction stimulated by the post-application bake—and causing the change in the mandrel pattern depicted by the transition from FIG. 1E to FIG. 1F—may proceed by any suitable choice of chemistry. In some embodiments, acetal formation via reaction of a hydroxy functional group (—OH) with an appropriate electrophile (such as an enol ether or an N-methoxymethylamide) may be used for crosslinking, with subsequent de-crosslinking accomplished with acid. Assuming for the sake of concreteness that the electrophile is an enol ether, a generic reaction scheme for the acetal crosslinking is:

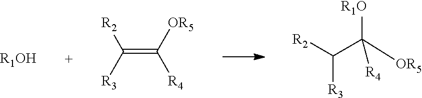

(In this scheme, groups R₁-R₅ will be left undefined, except to note that they should be organic.) Some DBARC (developable bottom anti-reflective coating) formulations include components that crosslink to form an acetal that also has anti-reflective properties. The DBARC film is resistant to aqueous solvents, such as tetramethylammonium hydroxide (TMAH), and may be overcoated with other materials, such as a photoresist. DBARC formulations typically contain a photoacid generator and can thus de-crosslink upon exposure and release of the acid, subsequently dissolving in TMAH. In some formulations, de-crosslinking of the acetal further results in the deprotection of an ester leaving group belonging to one of the components, causing the DBARC film to dissolve more readily. As another example of crosslinking chemistry, some positive-tone photoresist formulations include a film that crosslinks upon deposition and de-crosslinks upon generation of acid during an exposure step, allowing it to be removed subsequently by aqueous TMAH developer.

In various embodiments, this application discusses developing a formulation that enables the application of crosslinking chemistry in a film with specific resistance to organic solvent rather than the typical resistance to aqueous TMAH.

In various embodiments, this application discusses developing ROC formulations in the context of semiconductor fabrication to form a durable overcoat within tight constraints on bake temperature and bake time. The temperature at which crosslinking occurs in the overcoat must be lower than the glass transition temperature T_{g} of any photoresist on which it is coated; otherwise, the PAB used to set the overcoat might blur or destroy important features of the substrate. Typical values of T_{g} can be 150° C., 140° C., or even lower. In order for overcoat application to satisfy throughput and efficiency requirements for manufacturing in the semiconductor industry, the time within which crosslinking occurs has to be preferably comparable to that for other “front-end” track processes, e.g., less than 5 minutes. Microfabrication processes that are successful in their domain of application, such as etching, deposition, and treating surfaces, are generally not attractive candidates if the processing time is too long. Accordingly, it is a serious challenge to meet these constraints of lower temperature and shorter time for crosslinking, and to do so without the use of catalyst is even more challenging.

A third constraint arises from the chemistry itself. There is a distinction between the crosslinking reaction merely occurring in some portions of the overcoat to some limited extent (on the one hand) and the reaction occurring to a sufficiently full extent throughout the overcoat to provide robust resistance to an organic solvent (on the other). In other words, what is desired is a formulation that allows reversible crosslinking, confers organic solvent resistance, and may be applied and set at relatively low temperature and in a relatively short time.

The inventors performed experiments to assess various overcoat formulations. One set of experiments tested the formulations for crosslinking within the bake temperature and bake time constraints consistent with high-volume semiconductor manufacturing. A second set of experiments tested the formulations for resistance to organic solvent, principally methyl isobutyl carbinol (MIBC), a negative-tone developer in common use. A third set of experiments tested the formulations for facile de-crosslinking in the presence of acid, i.e., reversibility. In the formulations tested, the crosslinking chemistry included the reaction of a hydroxy functional group from either a phenolic moiety or a methacrylic acid moiety of a polymer with the vinyl ether functional group of a small-molecule crosslinker.

Formulations comprised a polymer (2.475-4.25% w/w), a small-molecule crosslinker (0.75-2.025% w/w), and one or more organic solvents (95-96% w/w total), usually MIBC with isoamyl ether (IAE). Multiple polymers were tested, including homopolymers, copolymers, and terpolymers incorporating 4-hydroxystyrene (PHS) in order to provide a phenolic content of 100, 70, 60, 50, or 30 percent of the polymer. Other constitutional units of certain polymers tested included n-butyl acrylate (nBA) and styrene (STY). Crosslinkers tested provided 2 or 3 vinyl ether functional groups.

The inventors expected that polymers with lower phenol content would be less soluble in MIBC, and would therefore become insoluble at lower crosslinking density, allowing for lower bake temperatures and/or shorter bake times. As a result, initial experiments focused on formulations including terpolymers relatively low in phenolic content. These experiments had unexpected results, however, leading to the discovery of an important parameter for robust crosslinking in this chemistry, the mole ratio between the total amounts present in the formulation of the phenolic moiety and the vinyl ether functional group. Initial experiments (reported in the first 6 rows of Table 1) showed that crosslinked films were generally resistant to TMAH, remaining coated on a wafer coupon after 30 seconds of exposure and even partially remaining after a more aggressive TMAH strip at 100° C. for 10 minutes. By contrast, the best of these initial formulations (4 nBA/PHS/STY:1 BTC:95 MIBC % w/w) required 10 minutes of baking at 140° C. to show resistance to an MIBC wash. This result indicated that the crosslinking density achieved by the formulation was not sufficient for films baked at lower temperatures and for shorter times to resist the MIBC. Such crosslinking would have to be significantly improved before use in microfabrication. Through additional experimentation and careful consideration of the phenolic:vinyl ether mole ratio, that improvement has been achieved, as disclosed herein in various embodiments.

FIG. 11 tabulates the results of additional crosslinking and solvent resistance experiments carried out with formulations providing a range of phenolic:vinyl ether mole ratios and baked for a range of temperatures and times. The formulations tested include different loadings of bi- and trifunctional crosslinkers. The inventors found that the choice of crosslinker and its absolute loading was less important for the resulting film's resistance to MIBC than the phenolic:vinyl ether mole ratio. In FIG. 11, a checkmark indicates that a film of the indicated composition and bake conditions exhibited a robust resistance to a 30 second MIBC wash. (An x represents no meaningful MIBC resistance; ˜ represents marginal resistance; and nt represents a condition under which a film was prepared but the solvent resistance was not tested.) Several formulations prepared with phenolic homopolymer and optionally filtered through a poly(tetrafluoroethylene) membrane passed this test with a bake temperature of 130° C. and a bake time of 5 minutes, appropriate for the intended semiconductor fabrication applications. Certain suitable formulations underwent sufficient crosslinking within an even shorter period of 2 minutes. Similar tests of formulations with phenol copolymers and terpolymers were also carried out. Sharp bounds on the phenolic:vinyl ether ratio yielding both crosslinking under bake conditions compatible with manufacturing and robust solvent resistance are not yet known, but there are indications that a value between 2.0 and 4.0 may be required.

The formulations prepared as described above, coated and crosslinked over a silicon wafer coupon, were tested for reversible de-crosslinking in two ways. The first test was to drop a solution of pTSA (5% w/w in propylene glycol methyl ether acetate, PGMEA) onto the crosslinked film at room temperature and to observe whether the coating remained on the substrate. In all cases, the crosslinked film dissolved instantaneously. Separate tests with neat PGMEA did not result in dissolution, indicating that the acid released by pTSA was required to de-crosslink.

The second de-crosslinking test was a bilayer study in which the crosslinked film was covered with an additional polymer overlayer, which was neat (in the control condition) or loaded with either pTSA or a TAG (in the experimental conditions). The assembled bilayer was then baked, causing acid released by pTSA or liberated from the TAG to diffuse from the overlayer into the film below. Without baking, the film remained crosslinked in the presence of both the TAG-loaded polymer and the neat polymer, with de-crosslinking occurring in the presence of the pTSA-loaded polymer. Baking caused de-crosslinking in the presence of the TAG-loaded polymer and enhanced de-crosslinking in the presence of the pTSA-loaded polymer, but no de-crosslinking was observed in the presence of the control polymer. These experimental conditions parallel the intended application, with acid diffusing from the underlying substrate to the overcoat during a PEB in order to define narrow features for subsequent negative-tone development.

These results may be summarized with reference to FIGS. 3-7, which will be discussed in turn below. The numerically subscripted “R” groups appearing in the chemical schemes of FIGS. 3, 4, and 7 may be understood as distinct chemical groups that may be chosen freely according to principles of organic chemistry and configured to the present application. Unless otherwise specified in the context of a certain embodiment, these “R” groups comprise a proximate carbon atom to which the explicitly specified structure is bound, and which may be bound in turn to any number of hydrocarbyl groups (including alkyl, alkenyl, alkynyl, or aryl groups, or combinations thereof) or cyclic hydrocarbon rings (including bonded or fused rings). Within these hydrocarbon structures, carbons and hydrogens may be substituted by or bonded with any number of heteroatoms (including but not limited to oxygen, nitrogen, phosphorus, sulfur, and the halogens), groups isoelectronic to carbon (tetrels replacing C, B—N replacing C—C, etc.), or functionalized organometallic sandwich compounds (such as the ferrocenyl group), as well as any additional hydrogens that may be necessary to close valences. Groups constructed along these lines without modification will be referred to with the shorthand “organic R groups.”

FIG. 3 depicts a composition 300 for overcoating structures, e.g., forming overcoat layer 124 (see FIG. 1E), during semiconductor microfabrication.

The composition 300 includes a first solute 302 comprising an organic hydroxy functional group, a second solute 304 comprising an enol ether functional group, and an organic solvent system 306. A ratio between an amount in moles of all of the organic hydroxy functional groups of the first solute 302 and an amount in moles of all of the enol ether functional groups 304 of the second solute may be between 2.0 and 4.0. The organic solvent system 306 comprises an organic solvent with boiling point above 120° C. at 1 bar and with relative permittivity below 40 for at least one temperature below 35° C. In certain embodiments, the composition 300 may further comprise a third solute comprising a weak acid catalyst 308 with generic formula HₛA and any number (s≥1) of ionizable protons.

In embodiments of the composition 300, R₁ is an organic R group. In embodiments of the composition 300, R₂, R₃, and R₄ may be organic R groups or may be chosen from among hydrogen and the halogens. In embodiments of the composition 300, R₅ may be an organic R group. In some embodiments, the group R₁ may comprise any number of additional hydroxy functional groups; in some such embodiments, the group R₁ may connect to or be the backbone of a polymer. In some embodiments, any of the groups R₂, R₃, R₄, and R₅ may comprise any number of additional enol ether functional groups; in some such embodiments, any of the groups R₂, R₃, R₄, and R₅ may connect to or be the backbone of a polymer. In certain embodiments, referring additionally to FIG. 5, the hydroxy functional group may be provided as the terminal —OH of a polymerized methacrylate ester 506, with R₁₂ being a hydrocarbyl chain; in one such embodiment, the polymerized methacrylate ester 506 may specifically be poly(hydroxyethylmethacrylate) 508.

FIG. 4 illustrates the components of embodiments of the composition of FIG. 3 comprising phenolic compositions.

In phenolic compositions 400, the hydroxy functional group may be provided as part of a phenolic moiety of a first solute 402, while the enol ether group is provided as a vinyl ether moiety of a second solute 404. An organic solvent system 406 may be of the same type as organic solvent system 306. In phenolic compositions 400, R₆, R₇, R₈, R₉, and R₁₀ may be organic R groups or may be chosen from among hydrogen and the halogens. In phenolic compositions 400, R₁₁ may be an organic R group. In some embodiments, any of the groups R₆, R₇, R₈, R₉, and R₁₀ may comprise any additional number of phenolic moieties; in some such embodiments, any of the groups R₆, R₇, R₈, R₉, and R₁₀ may connect to or be the backbone of a polymer. In some embodiments, R₁₁ may comprise any additional number of vinyl ether moieties; in some such embodiments, R₁₁ may connect to or be the backbone of a polymer.

In some embodiments of the composition 300 or of the phenolic compositions 400, the first solute 302 (respectively 402) may be a polymer 502 comprising constitutional units drawn from the set {nBA, PHS, STY}. In some embodiments, the polymer 502 may have an unknown or wholly random structure; in other embodiments, the polymer 502 may be represented as a defined sequence of constitutional repeating units labeled by index u, each of which appears nᵤ≥1 times in succession and comprises (in order) {xᵤ, yᵤ, zᵤ}≥0 constitutional units of nBA, PHS, and STY. In certain embodiments, the polymer 502 may be poly(4-hydroxystyrene) 504, corresponding to {xᵤ, yᵤ, zᵤ}={0, 1, 0} for a single constitutional unit u that appears nᵤ=n times. In other embodiments, the polymer 502 may be a copolymer of 4-hydroxystyrene (30-70%) and styrene (30-70%). In still other embodiments, the polymer 502 may be a terpolymer of n-butyl acrylate (15%), 4-hydroxystyrene (50-60%), and styrene (25-35%).

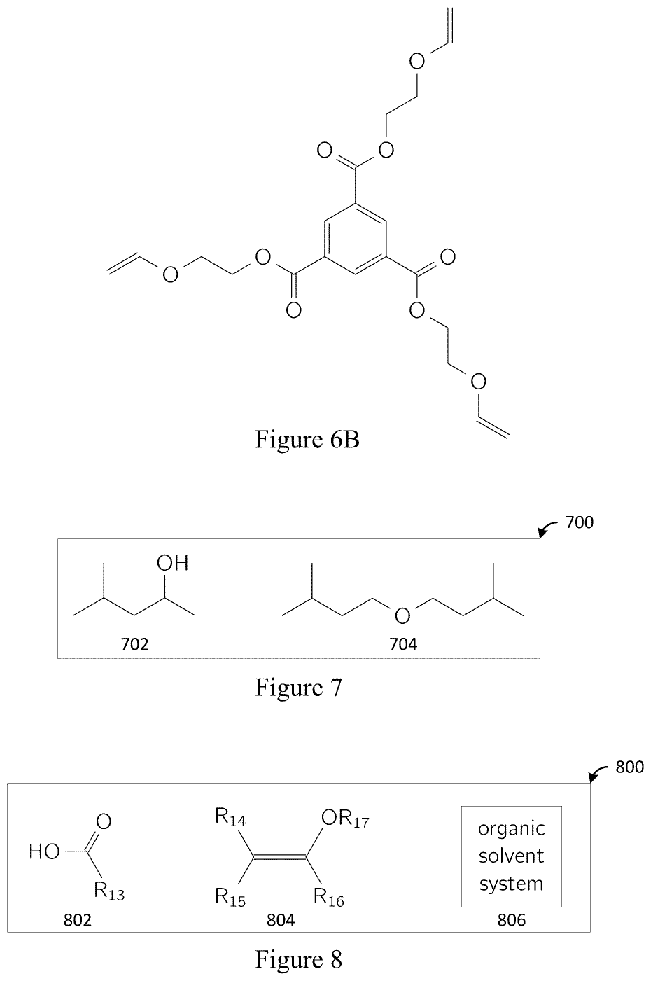

In some embodiments of the composition 300 or of the phenolic compositions 400, the second solute 304 (respectively 404) may be a multifunctional crosslinker. In certain embodiments, the multifunctional crosslinker may be 2,2-bis[4-[2-(vinyloxy)ethoxy]phenyl]propane (BPA-DEVE, depicted in FIG. 6A), which comprises two vinyl ether moieties. In other embodiments, the multifunctional crosslinker may be tris[2-(vinyloxy)ethyl]1,3,5-benzenetricarboxylate (BTC, depicted in FIG. 6B), which comprises three vinyl ether moieties. In still other embodiments preserving the value of the mole ratio between organic hydroxy (respectively phenolic) functional groups and enol ether (respectively vinyl ether) functional groups in the range between 2.0 and 4.0, the second solute 304 (respectively 404) may be another molecule with 2 or more vinyl ether moieties.

In certain embodiments of the composition 300 or of the phenolic compositions 400, the organic solvent system 306 (respectively 406) may comprise (as depicted in FIG. 7) a mixture 700, comprising methyl isobutyl carbinol (MIBC) 702 and isoamyl ether (IAE) 704. In other embodiments, the organic solvent system 306 (respectively 406) may comprise either of MIBC 702 and IAE 704, whether alone or in combination with additional organic solvent. Any additional solvents in such an embodiment may still have boiling point above 120° C. at 1 bar and with relative permittivity below 40 for at least one temperature below 35° C.

FIG. 8 depicts a composition 800 for overcoating structures, e.g., forming overcoat layer 124 (see FIG. 1E), during semiconductor microfabrication.

In various embodiments, the composition may include a first solute with a carboxylic acid functional group 802, a second solute with an enol ether functional group 804, and an organic solvent system 806. The general structure of a carboxylic acid functional group 802 is represented in FIG. 8, where R₁₃ represents the rest of the molecule, which could be a simple alkyl chain, an aromatic ring, or any other organic substituent. In some embodiments, the group R₁₃ may comprise any number of additional hydroxy functional groups; in some such embodiments, the group R₁₃ may connect to or be the backbone of a polymer. The enol ether functional group 804 may be similar to the enol ether functional group described above. Accordingly, as in prior embodiments, in embodiments of the composition 800, R₁₄, R₁₅, and R₁₆ may be organic R groups or may be chosen from among hydrogen and the halogens, and R₁₇ may be an organic R group. In some embodiments, any of the groups R₁₄, R₁₅, R₁₆, and R₁₇ may comprise any number of additional enol ether functional groups; in some such embodiments, any of the groups R₁₄, R₁₅, R₁₆, and R₁₇ may connect to or be the backbone of a polymer. The organic solvent system 806 may be of the same type as organic solvent system 306.

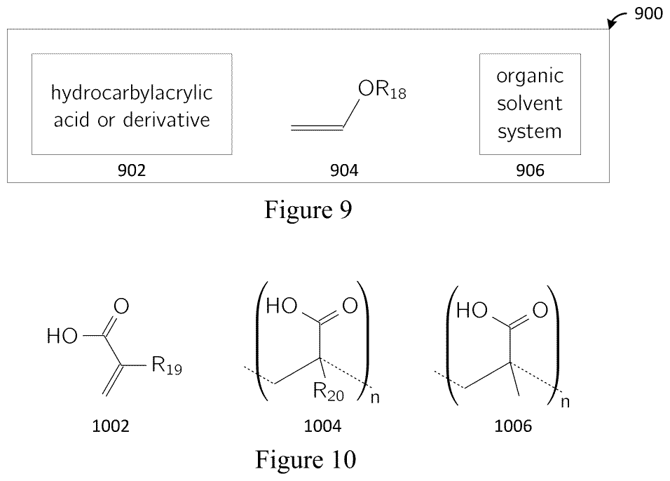

FIG. 9 illustrates the components of embodiments of the composition of FIG. 8 comprising hydrocarbylacrylic compositions.

In hydrocarbylacrylic compositions 900, the carboxylic acid functional group may be provided as part of a hydrocarbylacrylic acid or hydrocarbylacrylic acid derivative 902, while the enol ether group is provided as a vinyl ether moiety of a second solute 904. An organic solvent system 906 may be of the same type as organic solvent system 306.

FIG. 10 illustrates several possible choices of the first solute of FIG. 9, in accordance with embodiments.

In some embodiments of the composition 800 or of the hydrocarbylacrylic compositions 900, the first solute 802 (respectively 902) may be a hydrocarbylacrylic acid 1002, in which R₁₉ comprises a hydrocarbyl chain. In other embodiments, the first solute 802 (respectively 902) may be a polymer 1004 comprising a hydrocarbylacrylic constitutional repeating unit, in which R₂₀ comprises a hydrocarbyl chain. In certain embodiments, the polymer 1004 may be poly(methacrylic acid) 1006, corresponding to R₂₀=a methyl group, CH₃. In other embodiments in which the first solute 802 (respectively 902) may be a polymer comprising constitutional units in addition to a hydrocarbylacrylic acid, the polymer may be a copolymer of methacrylic acid (30-70%) and an n-butyl hydrocarbylacrylate, such as n-butyl acrylate or n-butyl methacrylate (30-70%). In other such embodiments, the first solute 802 (respectively 902) may be a terpolymer an n-butyl hydrocarbylacrylate (15%), methacrylic acid (50-60%), and styrene (25-35%).

The vinyl ether functional group 904 may be similar to the vinyl ether functional groups described above. Accordingly, as in prior embodiments, in embodiments of the composition 900, R₁₈ may be an organic R group. In some embodiments, R₁₈ may comprise any additional number of vinyl ether moieties; in some such embodiments, R₁₈ may connect to or be the backbone of a polymer.

In some embodiments of the composition 800 or of the hydrocarbylarylic compositions 900, the second solute 804 (respectively 904) may be a multifunctional crosslinker. In certain embodiments, the multifunctional crosslinker may be 2,2-bis[4-[2-(vinyloxy)ethoxy]phenyl]propane (BPA-DEVE, depicted in FIG. 6A), which comprises two vinyl ether moieties. In other embodiments, the multifunctional crosslinker may be tris[2-(vinyloxy)ethyl]1,3,5-benzenetricarboxylate (BTC, depicted in FIG. 6B), which comprises three vinyl ether moieties. In still other embodiments preserving the value of the mole ratio between carboxylic acid (respectively hydrocarbylacrylic acid or hydrocarbylacrylic acid derivative) functional groups and enol ether (respectively vinyl ether) functional groups in the range between 2.0 and 4.0, the second solute 804 (respectively 904) may be another molecule with 2 or more vinyl ether moieties.

In certain embodiments of the composition 800 or of the hydrocarbylacrylic compositions 900, the organic solvent system 806 (respectively 906) may comprise (as depicted in FIG. 7) a mixture 700, comprising methyl isobutyl carbinol (MIBC) 702 and isoamyl ether (IAE) 704. In other embodiments, the organic solvent system 806 (respectively 906) may comprise either of MIBC 702 and IAE 704, whether alone or in combination with additional organic solvent. Any additional solvents in such an embodiment may still have boiling point above 120° C. at 1 bar and with relative permittivity below 40 for at least one temperature below 35° C.

Compositions disclosed herein thus form a reversible overcoat that can be crosslinked within the bake time and bake temperature constraints of high-volume manufacturing, without the need for catalyst, and with resistance (when crosslinked) to an organic solvent, methyl isobutyl carbinol (MIBC). Formulations herein have a certain mole ratio between hydroxy functionality and enol ether functionality enabling sufficiently dense crosslinking, even at shorter bake times and lower bake temperatures, to withstand solvent strip. As discovered herein, the mole ratio between hydroxy functionality and enol ether functionality is preferably greater than 2.0 and less than 4.0 for crosslinking to occur at 140° C. (or lower) bake temperature and within 5 minutes (or shorter) bake time. If the ratio falls outside of this range, whether by the presence of too much or too little enol ether functionality relative to hydroxy functionality, higher temperatures and/or longer crosslinking times are required. In some embodiments, the hydroxy functionality is provided as part of a phenolic moiety. Other embodiments may have hydroxy groups that are not attached to an aromatic, for example, the carboxylic acid-OH groups of methacrylic acid or the terminal-OH groups of hydroxyethylmethacrylate.

In other embodiments, the composition can comprise a polymeric enol ether and a small molecule crosslinker with one or more hydroxy functional groups. Still other embodiments can comprise a blend of two or more polymers in which at least one has hydroxy functionality and another has enol ether functionality.

Accordingly, techniques herein provide reversible negative-tone develop acetal crosslinking in advanced track-based flow to pattern a substrate and form trenches at sub-lithographic resolution dimensions. The reversible crosslinking involves only organic solvents and can occur with or without acid catalysis. De-crosslinking can occur with acids as weak as pTSA or dodecylbenzenesulfonic acid.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

Those skilled in the art will also understand that there can be many variations made to the operations of the techniques explained above while still achieving the same objectives of the invention. Such variations are intended to be covered by the scope of this disclosure. As such, the foregoing descriptions of the embodiments of the invention are not intended to be limiting. Rather, any limitations to embodiments of the invention are presented in the following claims.

Example embodiments of the invention are described below. Other embodiments can also be understood from the entirety of the specification as well as the claims filed herein.

Example 1. A reversible overcoat composition for overcoating structures during semiconductor microfabrication includes a first solute, which includes an organic hydroxy functional group. The composition includes a second solute including an enol ether functional group, and an organic solvent system, where a ratio between an amount in moles of all of the organic hydroxy functional groups of the first solute and an amount in moles of all of the enol ether functional groups of the second solute is between 2.0 and 4.0.

Example 2. The composition of example 1, where the organic hydroxy functional group is not bound to a carbonyl as part of a carboxylic acid.

Example 3. The composition of one of examples 1 or 2, further includes a third solute that is a weak acid when dissolved in the organic solvent system.

Example 4. The composition of one of examples 1 to 3, where the organic hydroxy functional group is a phenolic functional group and the enol ether functional group is a vinyl ether functional group.

Example 5. The composition of one of examples 1 to 4, further includes a third solute that is a polyol.

Example 6. The composition of one of examples 1 to 5, further includes a third solute that is an alcohol, where the enol ether functional group includes polymeric vinyl ether.

Example 7. The composition of one of examples 1 to 6, where the ratio is between 2.8 and 3.8.

Example 8. The composition of one of examples 1 to 7, where the organic solvent system includes methyl isobutyl carbinol (MIBC) and isoamyl ether (IAE).

Example 9. The composition of one of examples 1 to 8, where the first solute is a polymer and the second solute is a small molecule with mass below 1000 daltons.

Example 10. The composition of one of examples 1 to 9, where the polymer is poly(4-hydroxystyrene) and the small molecule is 2,2-bis[4-[2-(vinyloxy)ethoxy]phenyl]propane (BPA-DEVE) or tris[2-(vinyloxy)ethyl]1,3,5-benzenetricarboxylate (BTC).

Example 11. The composition of one of examples 1 to 10, where the organic solvent system includes methyl isobutyl carbinol (MIBC) or isoamyl ether (IAE).

Example 12. The composition of one of examples 1 to 11, where the polymer is poly(hydroxyethylmethacrylate).

Example 13. The composition of one of examples 1 to 12, where the first solute is a small molecule with mass below 1000 daltons and the second solute is a polymer including second constitutional units.

Example 14. The composition of one of examples 1 to 13, where the first solute and the second solute are distinct polymers respectively including first constitutional units and second constitutional units.

Example 15. The composition of one of examples 1 to 14, where the organic solvent system includes an organic solvent with boiling point above 120° C. at 1 bar and with relative permittivity below 40 for at least one temperature below 35° C.

Example 16. A reversible overcoat composition for overcoating structures during semiconductor microfabrication includes a first solute, which includes a carboxylic acid functional group. The composition includes a second solute including an enol ether functional group, and an organic solvent system, where a ratio between an amount in moles of all of the carboxylic acid functional groups of the first solute and an amount in moles of all of the enol ether functional groups of the second solute is between 2.5 and 4.0.

Example 17. The composition of example 16, where the first solute is a polymer including first constitutional units and the second solute is a small molecule with mass below 1000 daltons.

Example 18. The composition of one of examples 16 or 17, where the polymer is poly(methacrylic acid).

Example 19. The composition of one of examples 16 to 18, where the first solute is a small molecule with mass below 1000 daltons and the second solute is a polymer including second constitutional units.

Example 20. The composition of one of examples 16 to 19, where the first solute and the second solute are distinct polymers respectively including first constitutional units and second constitutional units.

Example 21. The composition of one of examples 16 to 20, where the carboxylic acid functional group is part of or derived from a hydrocarbylacrylic acid and the enol ether functional group is a vinyl ether functional group.

Example 22. The composition of one of examples 16 to 21, where the organic solvent system includes an organic solvent with boiling point above 120° C. at 1 bar and with relative permittivity below 40 for at least one temperature below 35° C.

Example 23. A method of patterning a substrate includes forming a plurality of first mandrels over a substrate; coating an overcoat layer over the plurality of first mandrels, the overcoat layer being coated from a composition including: a first solute including an organic hydroxy functional group, the organic hydroxy functional group not being bound to a carbonyl as part of a carboxylic acid. The composition includes a second solute including an enol ether functional group; and an organic solvent system, where a ratio between an amount in moles of all of the organic hydroxy functional groups of the first solute and an amount in moles of all of the enol ether functional groups of the second solute is between 2.0 and 4.0. The method includes inducing a crosslinking reaction within the overcoat layer that renders the overcoat layer insoluble to a predetermined solvent and forming a crosslinked overcoat layer. The method includes exposing the substrate to a radiation to generate a plurality of acid particles within the plurality of first mandrels, and diffusing a portion of the plurality of acid particles from the plurality of first mandrels into portions of the crosslinked overcoat layer. The method includes inducing a decrosslinking reaction within the portions of the crosslinked overcoat layer and form de-crosslinked regions, where unmodified regions of the crosslinked overcoat layer form a plurality of second mandrels; and selectively removing the de-crosslinked regions, where the plurality of first mandrels and the plurality of second mandrels form a mandrel pattern over the substrate.

Example 24. The method of example 23, where inducing the crosslinking reaction includes baking at a temperature less than 150° C. and for less than 6 minutes.

Example 25. A method of patterning a substrate includes forming a plurality of first mandrels over a substrate, and coating an overcoat layer over the plurality of first mandrels, the overcoat layer being coated from a composition including: a first solute including a carboxylic acid functional group. The composition includes a second solute including an enol ether functional group; and an organic solvent system, where a ratio between an amount in moles of all of the carboxylic acid functional groups of the first solute and an amount in moles of all of the enol ether functional groups of the second solute is between 2.5 and 4.0. The method includes inducing a crosslinking reaction within the overcoat layer that renders the overcoat layer insoluble to a predetermined solvent and forming a crosslinked overcoat layer. The method includes exposing the substrate to a radiation to generate a plurality of acid particles within the plurality of first mandrels, and diffusing a portion of the plurality of acid particles from the plurality of first mandrels into portions of the crosslinked overcoat layer. The method includes inducing a decrosslinking reaction within the portions of the crosslinked overcoat layer and form de-crosslinked regions, where unmodified regions of the crosslinked overcoat layer form a plurality of second mandrels; and selectively removing the de-crosslinked regions, where the plurality of first mandrels and the plurality of second mandrels form a mandrel pattern over the substrate.

Example 26. The method of example 25, where inducing the crosslinking reaction includes baking at a temperature less than 150° C. and for less than 6 minutes.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A reversible overcoat composition for overcoating structures during semiconductor microfabrication, the composition comprising:
a first solute comprising an organic hydroxy functional group;
a second solute comprising an enol ether functional group; and
an organic solvent system, wherein a ratio between an amount in moles of all of the organic hydroxy functional groups of the first solute and an amount in moles of all of the enol ether functional groups of the second solute is between 2.0 and 4.0.

2. The composition of claim 1, wherein the organic hydroxy functional group is not bound to a carbonyl as part of a carboxylic acid.

3. The composition of claim 1, further comprising a third solute that is a weak acid when dissolved in the organic solvent system.

4. The composition of claim 1, wherein the organic hydroxy functional group is a phenolic functional group and the enol ether functional group is a vinyl ether functional group.

5. The composition of claim 1, further comprising a third solute that is a polyol.

6. The composition of claim 1, further comprising a third solute that is an alcohol, wherein the enol ether functional group includes polymeric vinyl ether.

7. The composition of claim 1, wherein the organic solvent system comprises methyl isobutyl carbinol (MIBC) or isoamyl ether (IAE).

8. The composition of claim 1, wherein the first solute is a polymer and the second solute is a small molecule with mass below 1000 daltons.

9. The composition of claim 8, wherein the polymer is poly(4-hydroxystyrene) and the small molecule is 2,2-bis[4-[2-(vinyloxy)ethoxy]phenyl]propane (BPA-DEVE) or tris[2-(vinyloxy)ethyl]1,3,5-benzenetricarboxylate (BTC).

10. The composition of claim 8, wherein the polymer is poly(4-hydroxystyrene), the small molecule is 2,2-bis[4-[2-(vinyloxy)ethoxy]phenyl]propane (BPA-DEVE) or tris[2-(vinyloxy)ethyl]1,3,5-benzenetricarboxylate (BTC), and the organic solvent system comprises methyl isobutyl carbinol (MIBC) or isoamyl ether (IAE).

11. The composition of claim 8, wherein the polymer is poly(hydroxyethylmethacrylate).

12. The composition of claim 1, wherein the first solute is a small molecule with mass below 1000 daltons and the second solute is a polymer.

13. A reversible overcoat composition for overcoating structures during semiconductor microfabrication, the composition comprising:
a first solute comprising a carboxylic acid functional group;
a second solute comprising an enol ether functional group; and
an organic solvent system, wherein a ratio between an amount in moles of all of the carboxylic acid functional groups of the first solute and an amount in moles of all of the enol ether functional groups of the second solute is between 2.5 and 4.0.

14. The composition of claim 13, wherein the first solute is a polymer and the second solute is a small molecule with mass below 1000 daltons.

15. The composition of claim 14, wherein the polymer is poly(methacrylic acid).

16. The composition of claim 13, wherein the first solute is a small molecule with mass below 1000 daltons and the second solute is a polymer.

17. The composition of claim 15, wherein the first solute and the second solute are distinct polymers.

18. The composition of claim 13, wherein the carboxylic acid functional group is part of or derived from a hydrocarbylacrylic acid and the enol ether functional group is a vinyl ether functional group.

19. The composition of claim 13, wherein the organic solvent system comprises an organic solvent with boiling point above 120° C. at 1 bar and with relative permittivity below 40 for at least one temperature below 35° C.

20. A method of patterning a substrate, the method comprising:
forming a plurality of first mandrels over a substrate;
coating an overcoat layer over the plurality of first mandrels, the overcoat layer being coated from a composition comprising:
a first solute comprising an organic hydroxy functional group;
a second solute comprising an enol ether functional group; and
an organic solvent system, wherein a ratio between an amount in moles of all of the organic hydroxy functional groups of the first solute and an amount in moles of all of the enol ether functional groups of the second solute is between 2.0 and 4.0;
inducing a crosslinking reaction within the overcoat layer that renders the overcoat layer insoluble to a predetermined solvent and forming a crosslinked overcoat layer;
exposing the substrate to a radiation to generate a plurality of acid particles within the plurality of first mandrels;
diffusing a portion of the plurality of acid particles from the plurality of first mandrels into portions of the crosslinked overcoat layer;
inducing a de-crosslinking reaction within the portions of the crosslinked overcoat layer to form de-crosslinked regions, wherein unmodified regions of the crosslinked overcoat layer form a plurality of second mandrels; and
selectively removing the de-crosslinked regions, wherein the plurality of first mandrels and the plurality of second mandrels form a mandrel pattern over the substrate.
